(19) United States
(12) Patent Application Publication
(10) Pub. No.: US 2007/0162797 A1
(43) Pub. Date: Jul. 12, 2007

(54) Test device and method for testing electronic devices

(76) Inventors: Thomas Janik, Muenchen (DE); Hans Schindlbeck, Muenchen (DE); Christoph-Maria Schroeder, Apex, NC (US)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/603,633

(22) Filed: Nov. 22, 2006

(30) Foreign Application Priority Data
Nov. 25, 2005 (DE) 10 2005 056 279.5

(51) Int. Cl. G01R 31/28

(52) U.S. Cl. 714/724

(57) ABSTRACT

A method for testing electronic devices, and to a test device that is, for test purposes, configured to be connected to an electronic system instead of an electronic device is disclosed. In one embodiment, the device includes at least one means for supplying a signal supplied by the electronic system and destined, in normal operation of the electronic system, for the electronic device, to a first electronic device that is configured to be connected to the device, and at least one further means for supplying a further signal supplied by the electronic system and destined, in normal operation of the electronic system, for the electronic device, to a second electronic device that is adapted to be connected to the device.

### CROSS-REFERENCE TO RELATED APPLICATIONS

This Utility Patent Application claims priority to German Patent Application No. DE 10 2005 056 279.5 filed on Nov. 25, 2005, which is incorporated herein by reference.

### FIELD OF THE INVENTION

The invention relates to a test device and to a method for testing electronic devices.

### BACKGROUND

In the case of conventional memory devices, in particular conventional semiconductor memory devices, one differentiates between so-called functional memory devices (e.g. PLAs, PALs, etc.), and so-called table memory devices, e.g. ROM devices (ROM=Read Only Memory) in particular PROMs, EPROMs, EEPROMs, flash memories, etc. and RAM devices (RAM=Random Access Memory or read-write memory), e.g. DRAMs and SRAMs.

In conventional electronic systems, e.g. mobile phones, digital cameras, PCs, laptops, PDAs, etc., a plurality of different types of semiconductor memory devices are frequently provided, as well as one or a plurality of microcontroller or microprocessor devices.

A RAM device is a memory for storing data under a predetermined address and for reading out the data again under this address later. Since as many memory cells as possible are to be accommodated in a RAM device, one has been trying to realize them as simply as possible.

In the case of SRAMs (SRAM=Static Random Access Memory), the individual memory cells consist of few, for example 6, transistors, and in the case of so-called DRAMs (DRAM=Dynamic Random Access Memory) in general only of one single, correspondingly controlled capacitive element (e.g. the gate-source capacitor of a MOSFET) with the capacitance of which one bit each can be stored as charge. This charge, however, remains for a short time only. Therefore, a so-called “refresh” must be performed regularly, e.g. approximately every 64 ms.

In contrast to that, no “refresh” has to be performed in the case of SRAMs, i.e., the data stored in the memory cell remain stored as long as an appropriate supply voltage is fed to the SRAM.

In the case of non-volatile memory devices (NVMs), e.g., ROMs, PROMs, EPROMs, EEPROMs, and flash memories, the stored data remain, however, stored even when the supply voltage is switched off.

In the case of ROM memory devices, the respective data may be predefined in the course of the manufacturing of a corresponding memory device (i.e., by the manufacturer) by making use of appropriate masks, e.g. in that a break, or a contact, is provided at the corresponding position of a corresponding memory cell matrix.

PROMs are read only memories that are programmable by the user. The respective memory cells may, for instance, include corresponding fuses (e.g. thin CrNi layers) that are blown by applying appropriate currents and can thus irreversibly be written with a date d=0. Alternatively, the respective memory cells may, for instance, also include specific Mosfets in which an additional, insulated, floating gate is provided. This is charged during the programming of a corresponding memory cell, this causing the threshold voltage of the respective Mosfet to be shifted.

EPROMs are multiply programmable read only memory devices, i.e., read only memories in which the respective programming may be reversed again by a corresponding deletion process by the user. As memory cells similar to some PROMs, e.g., Mosfets with an additional, insulated “floating gate” that is adapted to be correspondingly charged for programming may be used. By irradiating the EPROM with UV light, the floating gate charge of (all) Mosfets may be balanced again, and thus the programming may be reversed (for the entire EPROM).

An EEPROM is a multiple programmable read only memory device in which the respective programming may be reversed electrically, in contrast to an (UV erasable) EPROM, bit-, byte-, or page-wise.

A flash memory or flash EEPROM, respectively, is a medium between an EPROM and an EEPROM. A flash EEPROM is a multiply programmable read only memory that is like an EEPROM electrically erasable, however not bit- or byte-wise, but only correspondingly similar as an EPROM on the whole.

By the increasing miniaturization of electronic systems, a plurality of different semiconductor memory devices of varying types (and possibly additionally one or a plurality of microcontroller or microprocessor devices) are arranged in one and the same package.

In the case of so-called “MCP's” (MCP=Multiple Chip Package), for instance, one or a plurality of flash memory devices and one or a plurality of RAM memory devices may be provided in one and the same package, e.g., a NAND flash memory device or a NOR flash memory device, and a SDRAM memory device, etc.

In the case of so-called “SiP's” (SiP=System in Package), one or a plurality of microcontroller or microprocessor devices may be provided in one and the same package, and one or a plurality of possibly different memory devices, e.g. a microprocessor, a SDRAM memory device, and a NAND or NOR flash memory device, etc.

Furthermore, so-called “PoP” systems (PoP=Package on Package) are also known in prior art, in which a plurality of semiconductor device packages can be soldered on top of each other, and/or be arranged in one and the same package, etc.

Such packages i.e., have the disadvantage that they or devices that are to be provided therein individually (in particular with respect to their interaction with the respective electronic system) are difficult to test.

If, for instance, the operability of a SDRAM memory device that is to be incorporated into an MCP, in particular, e.g., into a SDRAM/flash MPC, is to be tested, the program stored on the flash memory device has to be known (since the flash memory device cooperates in a specific manner that has to be tested in the individual case with the SDRAM memory device). If the program is not known ,e.g., since the flash memory device originates from some other manufacturer than the SDRAM memory device to be tested, the program stored on the flash memory device has to be read out, this necessitating a soldering out of the MCP from a corresponding electronic system. However, the programs stored on flash memory devices or at least parts thereof are often subject to copy protection.

For these and other reasons there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic, exemplary representation of an electronic system in accordance with prior art viewed from the top.

FIG. 2 illustrates a schematic, exemplary representation of a device for testing semiconductor devices according to a first embodiment of the invention—viewed from the side, which is configured to be used for the system illustrated in FIG. 1.

FIG. 3 illustrates a schematic, exemplary representation of individual components of the test device illustrated in FIG. 2 each viewed from the top.

FIG. 4 a table illustrating several alternative possibilities of adjustment of the jumpers illustrated in FIGS. 2 and 3 during different tests that can be performed with the test device.

FIG. 5 illustrates a schematic, exemplary representation of a device for testing semiconductor devices in accordance with another embodiment of the invention viewed from the side.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a novel test device and a novel method for testing electronic devices.

In accordance with one embodiment of the invention there is provided a test device that is, for test purposes, configured to be connected to an electronic system instead of an electronic device. The device includes at least one means for supplying a signal supplied by the electronic system and destined, in normal operation of the electronic system, for the electronic device, to a first electronic device that is configured to be connected to the device, and at least one further means for supplying a further signal supplied by the electronic system and destined, in normal operation of the electronic system, for the electronic device, to a second electronic device that is adapted to be connected to the device.

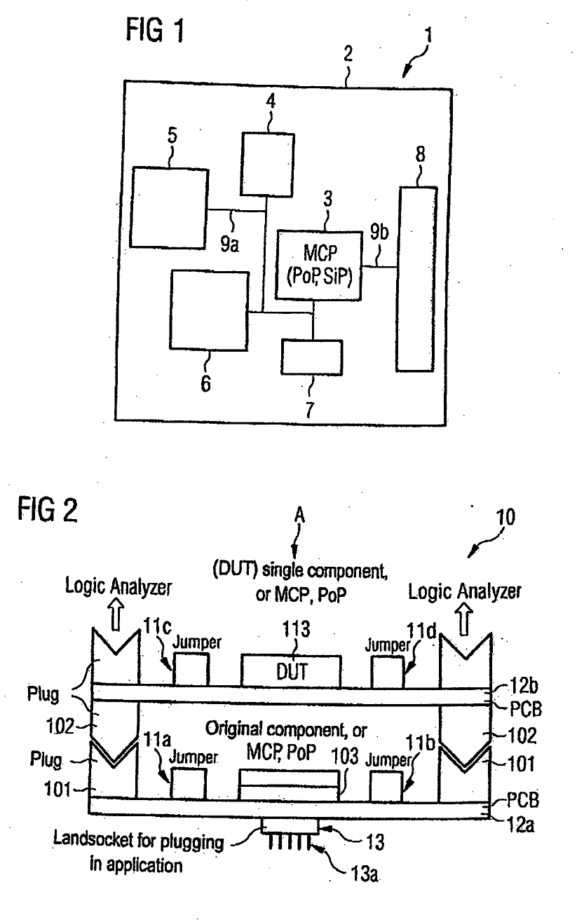

FIG. 1 illustrates a schematic, exemplary representation of an electronic system 1 (here: viewed from the top). The electronic system 1 includes a printed circuit board 2 on which a plurality of semiconductor devices 3, 4, 5, 6, 7, 8 are provided (or more exactly: a plurality of semiconductor device packages 3, 4, 5, 6, 7, 8 with respective semiconductor devices arranged therein).

The system 1 may, for instance, include one or a plurality of memory devices possibly of different types, and/or one or a plurality of microcontroller or microprocessor devices (possibly also of different types), etc. The semiconductor devices 3, 4, 5, 6, 7, 8 may be connected with each other via one or several bus systems 9a, 9b and exchange data with each other via the bus systems.

The bus systems 9a, 9b may, for instance, each comprise corresponding address, control, and reference data busses with corresponding address, control, and reference data lines. The electronic system 1 may, for instance, be destined for use in a mobile phone, or e.g. in a digital camera, a PC, a laptop, a PDA, etc., etc.

Since the dimensions of the electronic system 1 are to be selected as small as possible, a plurality of semiconductor memory devices- of the same type or of different types (and possibly additionally one or a plurality of microcontroller or microprocessor devices) may be arranged in one and the same package in one or a plurality of the above-mentioned semiconductor device packages 3, 4, 5, 6, 7, 8.

For example, in one or a plurality of the above-mentioned packages (here: in the semiconductor device package 3), a so-called “MCP” (MCP=Multiple Chip Package) may be used, in which one or a plurality of flash memory devices, and one or a plurality of RAM memory devices may be provided in one and the same package, e.g. a NAND flash memory device or a NOR flash memory device, and a SDRAM memory device.

Alternatively or additionally, in one or a plurality of the above-mentioned packages (e.g. in the semiconductor device package 3), a “SiP” (SiP=System in Package) may be used, in which one or plurality of microcontroller or microprocessor devices may be provided in one and the same package, and one or a plurality of possibly different memory devices, e.g. a microprocessor, a SDRAM memory device, and a NAND or NOR flash memory device, etc.

Alternatively or additionally, in one or a plurality of the above-mentioned packages (e.g. in the semiconductor device package 3), a “PoP” (PoP=Package on Package) may be used, in which a plurality of semiconductor device packages may be soldered or plugged on top of each other, and/or may be arranged in one and the same package, etc.

For the testing of the electronic system 1 or of individual elements that are to be provided therein or in appropriate systems, e.g. the MCP 3 illustrated in FIG. 1 (or SiP 3, or PoP 3, etc. or of a corresponding MCP or SiP or PoP), or of a SDRAM memory device and/or flash memory device, etc. to be provided therein or in a corresponding MCP (or SiP, PoP) in particular with respect to its/their cooperation with the system, the test device 10 illustrated in FIG. 2 may be used (here: viewed from the side).

For performing the test, the test device 10 illustrated in FIG. 2 is provided at the printed circuit board 2 illustrated in FIG. 1 instead of the semiconductor device or package 3 illustrated there (at the place of the printed circuit board 2 corresponding to that of the device or the package 3).

To this end, the test device 10 comprises a contact mechanism or contact means 13 (here: a landsocket means 13) arranged at the bottom side of a printed circuit board 12a (PCB=Printed Circuit Board), the contact means 13 comprising a plurality of pins 13a extending downward.

As will be explained in more detail in the following, the test device 10 or the contact means 13, respectively, is, for connecting the test device 10 to the electronic system 1 (after the dismounting, in particular the unplugging or soldering out of the semiconductor device or package 3 illustrated there) moved such from the top in the direction of the arrow A to the bottom to the upper side of the printed circuit board 2 of the electronic system 1 that the pins 13a of the contact means 13 of the test device 10 contact corresponding pads provided at the printed circuit board 2 or an adapter provided there, respectively.

The test device 10 is then electrically connected with the printed circuit board 2 namely such that the pins 13a of the contact means 13 contact corresponding lines (address, control, and reference data lines) of the above-mentioned bus systems 9a, 9b, like otherwise in the incorporated state of the device or package 3 illustrated in FIG. 1 corresponding pins that are provided at the device or the package 3.

A corresponding solder connection, or advantageously a (non-soldered, detachable) plug connection may, for instance, be provided for connecting the contact means 13 or the contact means pins 13a, respectively, with the printed circuit board 2 or the adapter provided there, respectively.

As results from FIG. 2, a device 103 or an “original component” (or a device package 103 with respective semiconductor devices arranged therein) may be provided on the printed circuit board 12a of the test device 10, which is/are, with respect to function, designed and equipped correspondingly or identically as the device or package 3 illustrated in FIG. 1 and dismounted for performing the test (in particular a corresponding or identical MCP 3 (or SiP 3, or PoP 3, etc.) with a corresponding or identical SDRAM memory device and/or flash memory device (and/or microcontroller or microprocessor device) provided therein, etc.).

Optionally, with one variant of the test, and as will be explained in more detail in the following, no semiconductor device 103 or no device 103 corresponding to the MCP 3 (or SiP 3, or PoP 3, etc.) may also be provided on the printed circuit board 12a other than illustrated in FIG. 2.

As results from FIG. 2, in the embodiment illustrated there, a further printed circuit board 12b (PCB=Printed Circuit Board) is arranged above the printed circuit board 12a, the printed circuit board 12b being electrically connected, via a corresponding plug contact 102 that is, e.g., provided at the bottom side of the printed circuit board 12b, with the printed circuit board 12a (or more exactly with a plug contact 101 provided at the upper side of the printed circuit board 12a).

For connecting the printed circuit boards 12a, 12b, again advantageously (non-soldered, detachable) plug connection (or alternatively a corresponding solder connection) is provided.

As results from FIG. 2, a (further) device 113 is arranged on the further printed circuit board 12b of the test device 10 (or a device package 113 with one or a plurality of semiconductor devices arranged therein, respectively).

As will be explained in more detail in the following, in a further variant of the test, no (further) semiconductor device 113 may also be provided on the further printed circuit board 12b, other than illustrated in FIG. 2.

The device 113 may, with respect to function, be designed and equipped correspondingly or identically as the device or package 3 illustrated in FIG. 1 and dismounted for performing the test (in particular correspondingly or identically as the MCP 3 (or SiP 3, or PoP 3, etc.) with a corresponding or identical SDRAM memory device and/or flash memory device (and/or microcontroller or microprocessor device) provided therein, etc.).

Alternatively, the device 113 may, with respect to function, also be designed and equipped correspondingly or identically as a resphective single one of the elements provided in the device or package 3 (MCP 3/SiP 3/PoP 3) illustrated in FIG. 1 dismounted for performing the test (“single component”).

The device 113 may, for instance, with respect to function, be correspondingly or identically or substantially identically designed and equipped as one respective (single) DRAM, in particular SDRAM memory device provided in the device or package 3 (MCP 3/SiP 3/PoP 3) dismounted for performing the test, or one (single) flash memory device (or microcontroller or microprocessor device, etc.) provided in the device or package 3 (MCP 3/SiP 3/PoP 3) dismounted for performing the test.

The device 113 arranged on the further printed circuit board 12b, in particular MCP/SiP/PoP, or SDRAM memory device (or flash memory device, or microcontroller or microprocessor device, etc.) may slightly differ from the corresponding device or package 3 (MCP 3/SiP 3/PoP 3) or from the corresponding SDRAM memory device/flash memory device/microcontroller or microprocessor device provided there dismounted for performing the test, in particular since the device or package 3 (or the corresponding DRAM or SDRAM memory device, and/or flash memory device) originates from some other manufacturer than the device 113 arranged on the further circuit board 12b (or the corresponding DRAM or SDRAM memory device, or flash memory device, etc.).

For mounting the device 113 on the further printed circuit board 12b, and/or for mounting the device 103 on the printed circuit board 103, a respective (non-soldered, detachable) plug connection may be used (or alternatively a corresponding solder connection).

After the mounting of the device 103 on the printed circuit board 12a, all the pins provided at the device 103 as the case may be, apart from one or several exception(s) that will be explained in more detail in the following are electrically connected with corresponding pads of the printed circuit board 12a, and via the contact means 13 and the pins 13a provided thereon, with the corresponding pads of the printed circuit board 2 of the electronic system 1 namely such that the pins of the device 103 each contact corresponding lines (address, control, and reference data lines) of the above-mentioned bus systems 9a, 9b, like otherwise in the incorporated state of the device or package 3 illustrated in FIG. 1 corresponding pins provided at the device or package 3 (as the case may be, apart from the one or the several above-mentioned exceptions).

Correspondingly similar, after the mounting of the device 113 on the further, upper printed circuit board 12b, all the pins provided at the device 113 apart from one or several exceptions that will be explained in more detail in the following are electrically connected with corresponding pads of the further printed circuit board 12b, and via the plug contacts 101, 102 of the further printed circuit board 12b and of the printed circuit board 12a and the contact means 13 of the printed circuit board 12a, and the pins 13a that are provided thereon, with the corresponding pads of the printed circuit board 2 of the electronic system 1.

Thus, it is achieved that correspondingly similar as with the device 103 the pins of the device 113 each contact corresponding lines (address, control, and reference data lines) of the above-mentioned bus systems 9a, 9b, like otherwise in the incorporated state of the device or package 3 illustrated in FIG. 1 corresponding pins that are provided at the device or package 3 (or like the pins of the corresponding single DRAM or single SDRAM memory device, or of the corresponding single flash memory device).

Thus (as the case may be, apart from one or several of the above-mentioned exceptions), the corresponding pins of the device 113 (or the pins of the corresponding single DRAM or single SDRAM memory device, or of the corresponding single flash memory device) are also electrically connected with the respectively corresponding pins of the device 103 (or the pins of the corresponding single DRAM or single SDRAM memory device, or of the corresponding single flash memory device).

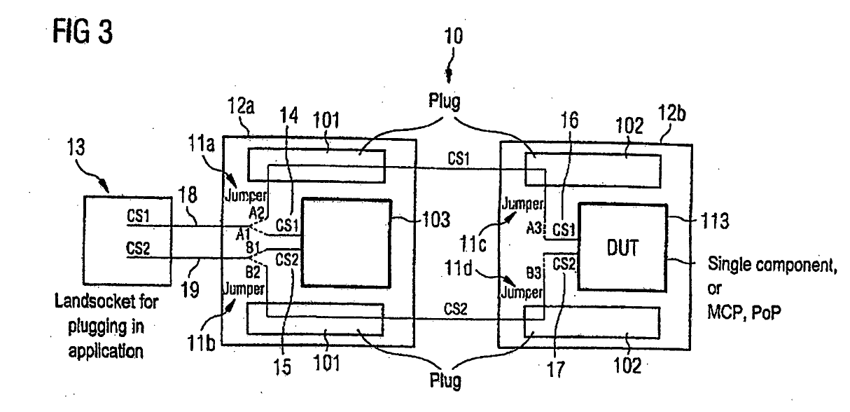

The above-mentioned applies as results, for instance, from FIG. 3 in the present embodiment not or just in a restricted way for the chip select pin(s) 14, 15 of the device 103, nor for the chip select pin(s) 16, 17 of the device 113 (and corresponding chip select pins 18, 19 of the contact means 13 provided on the printed circuit board 12a).

A first chip select pin 14 of the device 103 (which is, for instance, assigned to the corresponding single flash memory device of the device 103) is if available connected via a corresponding line to a first pin Al of a first jumper 11a that is provided on the printed circuit board 12a.

Correspondingly, a second chip select pin 15 of the device 103 (which is, for instance, assigned to the corresponding single DRAM or single SDRAM memory device of the device 103) is if available connected via a corresponding line to a first pin B1 of a second jumper 11b that is provided on the printed circuit board 12a.

Furthermore, a first chip select pin 16 of the device 113 (which is, for instance, assigned to the corresponding single flash memory device of the device 113) is if available connected via a corresponding line to a pin A3 of a first jumper 11c that is provided on the printed circuit board 12b, and a second chip select pin 17 of the device 113 (which is, for instance, assigned to the corresponding single DRAM or single SDRAM memory device of the device 113) is if available connected via a corresponding line to a pin B3 of a second jumper 11d that is provided on the printed circuit board 12b.

A further pin of the first jumper 11c of the printed circuit board 12b is, via a corresponding line, connected with the above-mentioned plug contact 102 of the printed circuit board 12b, and thus electrically connected with the plug contact 101 of the printed circuit board 12a, and via a corresponding line with a second pin A2 of the first jumper 11a that is provided on the printed circuit board 12a.

Correspondingly similar, a further pin of the second jumper 11d of the printed circuit board 12b is, via a corresponding line, connected with the above-mentioned plug contact 102 of the printed circuit board 12b, and thus electrically connected with the plug contact 101 of the printed circuit board 12a, and via a corresponding line with a second pin B2 of the second jumper 11b that is provided on the printed circuit board 12a.

A further pin of the first jumper 11a that is provided on the printed circuit board 12a is, via a corresponding line, connected with the chip select pin 18 of the contact means 13 (and thus with a corresponding chip select pin 13a of the contact means 13); correspondingly, a further pin of the second jumper 11b that is provided on the printed circuit board 12a is also, via a corresponding line, connected with the chip select pin 19 of the contact means 13 (and thus with a corresponding further chip select pin 13a of the contact means 13).

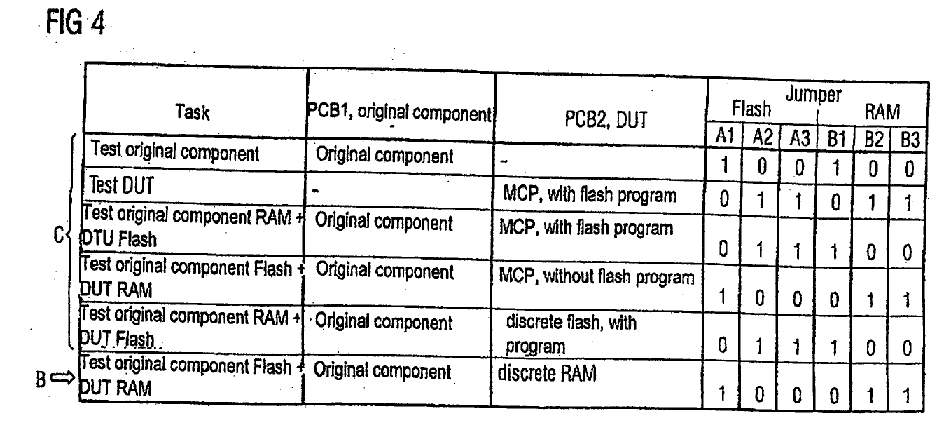

In the first jumper 11a of the printed circuit board 12a, the above-mentioned further jumper pin is either connected in a conductive manner with the above-mentioned first jumper pin A1 (state “1” of the jumper pin A1 according to the table illustrated in FIG. 4), or the above-mentioned further jumper pin of the first jumper 11a of the printed circuit board 12a is electrically disconnected from the first jumper pin A1 of the first jumper 11a (state “0” of the jumper pin A1 according to the table illustrated in FIG. 4).

Correspondingly, with the first jumper 11a of the printed circuit board 12a, the above-mentioned further jumper pin is either connected in a conductive manner with the above-mentioned second jumper pin A2 (state “1” of the jumper pin A2 according to the table illustrated in FIG. 4), or the above-mentioned further jumper pin of the first jumper 11a of the printed circuit board 12a is electrically disconnected from the above-mentioned second jumper pin A2 of the first jumper 11a (state “0” of the jumper pin A2 according to the table illustrated in FIG. 4).

Correspondingly, with the second jumper 11b of the printed circuit board 12a, the above-mentioned further jumper pin is either connected in a conductive manner with the above-mentioned first jumper pin B1 of the second jumper 11b (state “1” of the jumper pin B1 according to the table illustrated in FIG. 4), and the further jumper pin of the second jumper 11b is electrically disconnected from the above-mentioned second jumper pin B2 of the second jumper 11b (state “0” of the jumper pin B2 according to the table illustrated in FIG. 4), or vice versa with the second jumper 11b, the above-mentioned further jumper pin is electrically disconnected from the first jumper pin B1 of the second jumper 11b (state “0” of the jumper pin B1), and the further jumper pin of the second jumper 11b is connected with the above-mentioned second jumper pin B2 of the second jumper 11b (state “1” of the jumper pin B2).

In a similar manner, with the first jumper 11c of the printed circuit board 12b, the above-mentioned further jumper pin is either connected in a conductive manner with the above-mentioned jumper pin A3 (state “1” of the jumper pin A3), or the above-mentioned further jumper pin of the first jumper 11c of the printed circuit board 12b is electrically disconnected from the above-mentioned jumper pin A3 of the first jumper 11c (state “0” of the jumper pin A3).

Correspondingly, with the second jumper 11d of the printed circuit board 12b, the above-mentioned further jumper pin is either connected in a conductive manner with the above-mentioned jumper pin B3 (state “1” of the jumper pin B3), or the above-mentioned further jumper pin of the second jumper 11d of the printed circuit board 12b is electrically disconnected from the above-mentioned jumper pin B3 of the second jumper 11d (state “0” of the jumper pin B3).

The conductive connecting (or the electrical disconnecting) of the corresponding jumper pins may, for instance, be performed by the providing (or the interrupting) of corresponding solder connections, or by the switching of corresponding, mechanical (e.g. manually operable) switches, etc.

Whenever or only if the jumper pin A1 of the first jumper 11a of the printed circuit board 12a is in a state, 1”, a chip select signal CS1 that is present at a corresponding control line of the bus system 9a, 9b is, via the chip select pin 18 of the contact means 13 and the first jumper 11a of the printed circuit board 12a, transmitted to the corresponding chip select pin 14 of the device 103 which is, for instance, assigned to the corresponding single flash memory device of the device 103.

Correspondingly, whenever or only if the jumper pin B1 of the second jumper 11b of the printed circuit board 12a is in a state “1”, a chip select signal CS2 that is present at a corresponding further control line of the bus system 9a, 9b is, via the chip select pin 19 of the contact means 13 and the second jumper 11b of the printed circuit board 12a, transmitted to the corresponding chip select pin 15 of the device 103 which is, for instance, assigned to the corresponding single DRAM or single SDRAM memory device of the device 103.

As results from FIG. 3, furthermore, whenever or only if the jumper pin A2 of the first jumper 11a of the printed circuit board 12a is in a state “1” and additionally the jumper pin A3 of the first jumper 11c of the printed circuit board 12b is also in a state “1”, a chip select signal CS1 that is present at the corresponding control line of the bus system 9a, 9b is, via the chip select pin 18 of the contact means 13, the first jumper 11a of the printed circuit board 12a, the plug contacts 101, 102, and the first jumper 11c of the printed circuit board 12b, transmitted to the corresponding chip select pin 16 of the device 113 which is, for instance, assigned to the corresponding single flash memory device of the device 113.

Correspondingly similar, whenever or only if the jumper pin B2 of the second jumper 11d of the printed circuit board 12b is in a state “1” and additionally the jumper pin B3 of the second jumper 11d of the printed circuit board 12b is also in a state “1”, a chip select signal CS2 that is present at the corresponding control line of the bus system 9a, 9b is, via the chip select pin 19 of the contact means 13, the second jumper 11b of the printed circuit board 12a, the plug contacts 101, 102, and the second jumper 11d of the printed circuit board 12b, transmitted to the corresponding chip select pin 17 of the device 113 which is, for instance, assigned to the corresponding single DRAM or single SDRAM memory device of the device 113.

Only if the corresponding device 103, 113 or the corresponding single DRAM or single SDRAM memory device or single flash memory device, respectively, receives a corresponding chip select signal CS1, CS2 at the respective chip select pin is it actually addressed and reacts to the corresponding address, control, (reference) data signals received at the remaining pins.

This way it is possible—by different adjustment of the jumpers 11a, 11b, 11c, 11d (cf. also the table illustrated in FIG. 4) to specifically use arbitrarily, for test purposes, either one or a plurality of components provided on the device 103 and/or on the device 113 during a normal operation (apart from the connection of the test device 10) of the electronic system 1.

This will be explained in more detail with reference to the case illustrates in the last line B of the table illustrated in FIG. 4.

In this case, e.g. an appropriate MCP (with an appropriate DRAM memory device, in particular SDRAM memory device, and flash memory device) is used as device 103, and as device 113 e.g. a single DRAM, in particular a single SDRAM memory device is used, which may be constructed and equipped identically or similarly to the DRAM memory device, in particular SDRAM memory device provided in the MCP 103 used as device 103.

Due to the corresponding adjustments of the jumpers 11a, 11b, 11c, 11d (jumper pins Al, B2, and B3 in the state “1”, and jumper pins A2, A3, and B1 in the state “0”) illustrated in FIG. 4, a chip select signal CS1 that is present at the corresponding control line of the bus system 9a, 9b is transmitted to the corresponding chip select pin 14 that is assigned to the flash memory device of the MCP 103 of the printed circuit board 12a, and a chip select signal CS2 that is present at the corresponding control line of the bus system 9a, 9b is transmitted to the corresponding chip select pin 17 of the single DRAM, in particular single SDRAM memory device 113 of the printed circuit board 12b (not, however, to the chip select pin 15 assigned to the DRAM, in particular SDRAM memory device of the MCP 103 of the printed circuit board 12a).

In the course of a “normal” operation apart from the connection of the test device 10—of the electronic system 1 performed for test purposes, exclusively the flash memory device of the MCP 103 of the printed circuit board 12a and the single DRAM, in particular single SDRAM memory device 113 of the printed circuit board 12b are then addressed as far as the test device 10 is concerned.

Thus, the single DRAM, in particular single SDRAM memory device 113 may be tested as “DUT” (DUT=Device under Test) under conditions that come close to real conditions (in particular with respect to the cooperation of the memory device 113 with the electronic system 1), without the program stored on the flash memory device having to be known.

The control, address, and/or reference data signals exchanged between the device 113, in particular the single DRAM or single SDRAM memory device 113, and/or between the device 103 and the electronic system 1 (or among the devices 113, 103, respectively) may, for instance, be tapped at the plug contacts 101, 102 and fed e.g. to a logic analyzer or oscilloscope for analysis purposes.

In the remaining lines C of the table illustrated in FIG. 4, further, conceivable possibilities of adjustment of the jumpers 11a, 11b, 11c, 11d illustrated in FIGS. 2 and 3 are shown during further tests that may be performed with the test device 10.

In the tests, a respective signal termination—preventing a floating state of the corresponding pin 14, 15, 16, 17—is provided for those chip select pins 14, 15, 16, 17 of the devices or memory devices 113, 103 that are connected with ajumper pin A1, A2, A3, B1, B2, B3 that is in the state “1”. For instance, corresponding 0-active signals or “logic low” active signals may be used as chip select signals CS1, CS2. By the above-mentioned signal termination of the chip select pins 14, 15, 16, 17 that are connected with ajumper pin A1, A2, A3, B1, B2, B3 in the state “0”, it will be ensured that the corresponding pins are kept in a state 1 (“logic high” inactive), i.e. the assigned devices or memory devices 113, 103 remain deselected.

In further, alternative embodiments that are not illustrated here, one or several further signals (or alternatively all signals relating to the device 103 and/or 113 (or—actually—to the device 3), e.g. one or several clock signals supplied by the electronic system 1, etc. is/are dealt with in a way corresponding to that explained above for the chip select signals CS1, CS2 with respect to the transmission or non-transmission of the corresponding signals CS1, CS2 to the device 103, and/or 113.

To this end, one or several further jumpers the structure and function of which correspond to that of the first jumper 11a (which each comprise, for instance, three pins, like the jumper 11a) may be provided on the printed circuit board 12a, and one or several further jumpers the structure and function of which correspond to that of the second jumper 11b (which each comprises three pins, like the jumper 11b). Correspondingly, one or several further jumpers the structure and function of which correspond to that of the jumper 11c (which each comprise, like the jumper 11c, two pins), and one or several further jumpers the structure and function of which correspond to that of the jumper 11d (which each comprise two pins, like the jumper 11d), may be provided on the printed circuit board 12b.

The further jumpers are preferably each placed in an identical state as the respective jumper 11a, 11b, 11c, 11d assigned to them (cf. e.g. the table illustrated in FIG. 4).

Thus, it may be achieved that the signal(s) that is/are correspondingly transmitted, or not transmitted, via the above-mentioned further jumpers, e.g. the above-mentioned clock signal(s), each is/are only supplied to exactly that device 103, 113 (or the corresponding flash memory device/DRAM memory device, respectively) that is addressable by corresponding chip select signals CS1, CS2 due to the respective state of the jumpers 11a, 11b, 11c, 11d (and not additionally also unnecessarily to devices that are not addressable at all due to the state of the jumpers 11a, 11b, 11c, 11d). Thus, a falsification of the corresponding signals(s) by the non-addressable device is prevented.

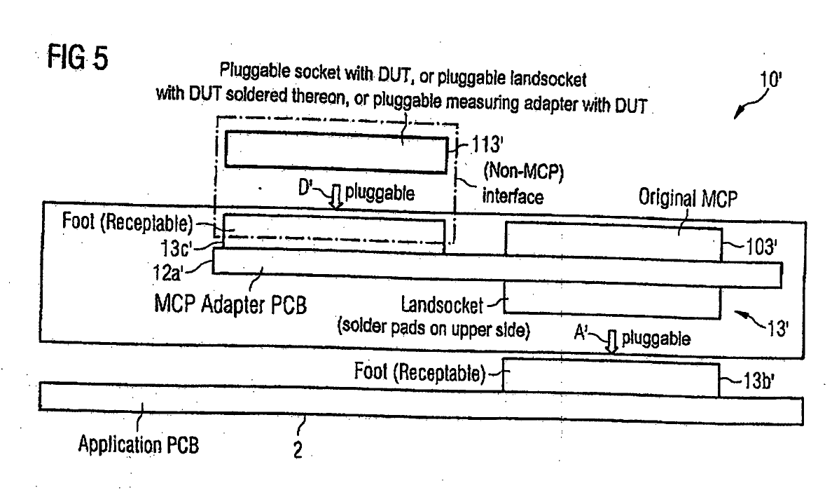

FIG. 5 illustrates a schematic, exemplary representation of a device 10′ for testing semiconductor devices in accordance with a further, alternative embodiment of the invention.

The functioning of the device 10′ is substantially identical as explained above with respect to the device 10 illustrated in FIGS. 2 and 3.

However, the device 10′ only comprises one single printed circuit board 12a′ on which both the device package or device 103′ corresponding to the device package or device 103 illustrated in FIGS. 2 and 3 and the device package or device 113 ′ corresponding to the device package or device 113 illustrated in FIGS. 2 and 3 are arranged.

For connecting the device 10′ to the electronic system 1, a contact means 13′, in particular a corresponding landsocket means, that is provided at the bottom side of the printed circuit board 12a′ is moved such from the top in the direction of an arrow A′ to the bottom to the upper side of the printed circuit board 2 of the electronic system 1 that pins provided at the contact means 13′ contact corresponding pads provided at an adapter 13′ that is provided at the printed circuit board 2. As an adapter 13b′, e.g. a corresponding foot adapter that is soldered to the printed circuit board 2, e.g. a surface-mounted BGA foot adapter, may be used.

Correspondingly similar, for connecting the device package or device 113′ to the printed circuit board 12a′, a contact means, in particular a corresponding landsocket means, that is soldered to the device 113′ may, for instance, be moved such from the top in the direction of an arrow D′ to the bottom to the upper side of the printed circuit board 12a′ that pins provided at the contact means contact corresponding pads provided at an adapter 13c′ that is fixed to the printed circuit board 12a′. As an adapter, a corresponding foot adapter—that is soldered to the printed circuit board 12a′ —, e.g. a surface-mounted BGA foot adapter, etc. may again be used. Instead of a (pluggable) landsocket with the device 113′ soldered thereon, a pluggable measuring adapter may, for instance, also be used which is connected with the device 113′, or any other in particular pluggable socket carrying the device 113′.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A test device that is, for test purposes, connected to an electronic system instead of an electronic device, wherein the test device comprises:
a first signal supplied by the electronic system to a first electronic device that is adapted to be connected to the test device; and
a second signal supplied by the electronic system and destined, in normaly operation of the electronic system to a second electronic device that is connected to the test device.

2. The device according to claim 1, comprising wherein the first and second electronic device comprise at least two semiconductor devices or microchips.

3. The device according to claim 1, wherein the first signal and the second signal are optionally supplied to the first and second electronic device.

4. The device according to claim 1, comprising wherein the first signal is supplied via a jumper.

5. The device according to claim 2, comprising wherein the first signal is supplied to a first semiconductor device, and the second signal to a semiconductor device.

6. The device according to claim 5, wherein the semiconductor device of the second electronic device is substantially identically structured and equipped as a second semiconductor device of the first electronic device.

7. The device according to claim 1, comprising wherein the first signal is a chip select signal.

8. The device according to claim 1, comprising: for connection to the electronic system, a contact configured to connect the first electronic device to the test device.

9. A test device that is, for test purposes, configured to be connected to an electronic system instead of an electronic device, wherein the device comprises:
at least one means for supplying a signal supplied by the electronic system and destined, in normal operation of the electronic system, for the electronic device, to a first electronic device that is adapted to be connected to the test device;
and at least one further means for supplying a further signal supplied by the electronic system and destined, in normal operation of the electronic system, for the electronic device, to a second electronic device that is adapted to be connected to the test device.

10. The device according to claim 9, comprising wherein the first and/or second electronic device that is configured to be connected to the device comprise at least two semiconductor devices or microchips, respectively.

11. The device according to claim 9, wherein the means and/or the further means is/are designed such that the signal and/or the further signal are configured to be optionally supplied to the first and/or second electronic device configured to be connected to the device.

12. The device according to claim 9, comprising wherein the means and/or the further means is/are jumper means.

13. The device according to claim 10, comprising wherein the signal is supplied to a first semiconductor device or microchip, respectively, of the first electronic device that is configured to be connected to the device, and the further signal to a semiconductor device or microchip, respectively, of the second electronic device that is configured to be connected to the device.

14. The device according to claim 13, wherein the semiconductor device of the second electronic device that is configured to be connected to the device is substantially identically structured and equipped as a second semiconductor device of the first electronic device that is configured to be connected to the device.

15. The device according to claim 9, comprising wherein the signal and/or the further signal are chip select signals.

16. The device according to claim 9, comprising, for connection to the electronic system, a contact means that is of identical design as a contact means of the first and/or second electronic devices that are adapted to be connected to the device.

17. The device according to claim 9, comprising, for connection to the electronic system, a contact means that is of identical design as a contact means of the electronic device that is, in normal operation, connected to the electronic system instead of the device.

18. The device according to claim 9, comprising wherein the first and/or second electronic device(s) that is/are configured to be connected to the device is/are MCP devices.

19. The device according to any of claims 9, comprising wherein the first and/or second electronic devices that are configured to be connected to the device is/are PoP devices.

20. The device according to any of claims 9, comprising wherein the first and/or second electronic devices that are configured to be connected to the device are SiP devices.

21. The device according to claim 13, comprising wherein the first semiconductor device of the first electronic device that is configured to be connected to the device is a flash memory device, and the semiconductor device of the second electronic device that is configured to be connected to the device is a RAM memory device.

22. A method for testing electronic devices by using a test device that is, for test purposes, adapted to be connected to an electronic system instead of an electronic device, the method comprising:
supplying a signal that is, in normal operation of the electronic system, destined for the electronic device, to a first electronic device that is adapted to be connected to the device; and
supplying a further signal that is, in normal operation of the electronic system, destined for the electronic device, to a second electronic device that is adapted to be connected to the device.
